(19) United States
(12) Patent Application Publication
(10) Pub. No.: US 2025/0300426 A1
(43) Pub. Date: Sep. 25, 2025

(54) LASER MODULE

(71) Applicant: HAMAMATSU PHOTONICS K.K., Hamamatsu-shi (JP)

(72) Inventors: Shohei HAYASHI, Hamamatsu-shi (JP); Kazuue FUJITA, Hamamatsu-shi (JP); Akio ITO, Hamamatsu-shi (JP)

(73) Assignee: HAMAMATSU PHOTONICS K.K., Hamamatsu-shi (JP)

(21) Appl. No.: 19/081,171

(22) Filed: Mar. 17, 2025

(30) Foreign Application Priority Data
Mar. 21, 2024 (JP) 2024-045165

(51) Int. Cl. H01S 5/028; H01S 5/02315; H01S 5/34

(52) U.S. Cl. CPC H01S 5/0287; H01S 5/02315; H01S 5/3402

(57) ABSTRACT

A laser module includes a support substrate, a QCL element, a resin layer, and an emission direction defining portion. The QCL element includes a substrate that has a front surface for emitting a terahertz wave and a semiconductor multilayer structure that includes an active layer generating the terahertz wave. The emission direction defining portion is provided on an upper surface of the resin layer and is configured to emit the terahertz wave, which is emitted from the front surface of the substrate, to the outside from the upper surface. The resin layer contacts the front surface of the substrate and extends in a front-rear direction when viewed in a vertical direction. The height position of the upper surface of the resin layer with respect to the support surface of the support substrate reaches at least the height position of the upper surface of the substrate.

### TECHNICAL FIELD

The present disclosure relates to a laser module.

### CROSS-REFERENCE TO RELATED APPLICATIONS

This application claims the benefit of priority from Japanese Patent Application No. 2024-045165 filed on Mar. 21, 2024, the entire contents of which are incorporated herein by reference.

### BACKGROUND

Conventionally, a difference-frequency-generation type terahertz quantum cascade laser (DFG-THz-QCL: Difference Frequency Generation THz-Quantum Cascade Laser) is known. For example, Patent Document 1 (U.S. Patent Application Publication No. 2015/0311665) discloses polishing an end surface of a substrate constituting a terahertz quantum cascade laser (the terahertz-wave emission side surface) so that it is inclined relative to an end surface of an active layer, thereby avoiding total reflection of a terahertz wave at that end surface.

### SUMMARY

There exists a need to efficiently extract a terahertz wave from a DFG-THz-QCL to the outside. However, as disclosed in Patent Document 1, the process of polishing the end surface of the substrate is relatively difficult and can reduce productivity of the DFG-THz-QCL.

In view of the above, one aspect of the present disclosure is to provide a laser module capable of improving productivity while enhancing the efficiency of extracting a terahertz wave to the outside.

The present disclosure includes the following laser modules [1] through [16].

[1]A laser module including: a support body having a support surface; a quantum cascade laser element disposed on the support surface; a resin layer disposed on the support surface; and an emission direction defining portion disposed on the resin layer, wherein the quantum cascade laser element includes: a substrate having a first surface facing the support surface, a second surface on an opposite side of the first surface, and a third surface connecting the first surface and the second surface and configured to emit a terahertz wave; and a semiconductor multilayer structure provided on the second surface of the substrate, the semiconductor multilayer structure including an active layer configured to generate a first pump light of a first frequency and a second pump light of a second frequency, and generate the terahertz wave of a difference frequency between the first frequency and the second frequency by difference frequency generation using the first pump light and the second pump light, wherein the resin layer has a fourth surface facing the support surface and a fifth surface on an opposite side of the fourth surface, wherein the emission direction defining portion is provided on the fifth surface and is configured to emit the terahertz wave emitted from the third surface of the substrate to an outside from the fifth surface in a direction facing the fifth surface, wherein the resin layer is in contact with the third surface of the substrate and extends in a second direction along an emission direction of the terahertz wave from the third surface when viewed in a first direction in which the first surface and the second surface face each other, and wherein a height position of the fifth surface of the resin layer with respect to the support surface reaches at least a height position of the second surface of the substrate with respect to the support surface.

The laser module of [1] described above is formed as a DFG-THz-QCL that generates a terahertz wave by difference frequency generation. According to the laser module described above, bringing a resin layer, whose refractive index difference from the substrate of the quantum cascade laser element is smaller than that of air, into contact with the third surface of the substrate can suppress total reflection of the terahertz wave at the interface between the third surface and air, which otherwise would be problematic when emitting the terahertz wave into air. Consequently, the terahertz wave can be efficiently propagated from the substrate of the quantum cascade laser element to the resin layer, and then emitted in a direction (i.e., the direction facing the fifth surface) specified by the emission direction defining portion through the interior of the resin layer. Thus, according to the laser module, productivity (yield) can be enhanced with a relatively simple configuration, and the efficiency of extracting the terahertz wave to the outside can be improved.

[2] The laser module according to [1], further comprising a reflective layer disposed between the support surface of the support body and the first surface of the substrate, and between the support surface of the support body and the fourth surface of the resin layer, and configured to reflect the terahertz wave.

According to the configuration of [2], in the quantum cascade laser element, a terahertz wave emitted in an oblique direction-tilted downward (toward the support surface side) relative to the second direction—from the third surface of the substrate can be prevented from propagating into the support body. By reflecting it with the reflective layer toward the resin layer side, the extraction efficiency of the terahertz wave can be further increased.

[3] The laser module according to [1] or [2], further comprising a reflective layer provided on an end surface of the substrate in the second direction on a side opposite to the third surface, and configured to reflect the terahertz wave.

According to the configuration of [3], by reflecting the terahertz wave with the reflective layer at the end surface of the substrate located on an opposite side from the third surface, it is possible to increase the amount of terahertz-wave light that travels from that end surface toward the third surface side. This can further effectively improve the extraction efficiency of the terahertz wave.

[4] The laser module according to any one of [1] to [3], further comprising a reflective layer provided on a side surface of the substrate intersecting a third direction that is perpendicular to both the first direction and the second direction, and configured to reflect the terahertz wave.

According to the configuration of [4], a terahertz wave trying to exit through the side surface of the substrate can be reflected back into the substrate by the reflective layer, thereby increasing the amount of terahertz-wave light emitted from the third surface. This can further effectively increase the extraction efficiency of the terahertz wave.

[5] The laser module according to any one of [1] to [4], wherein the emission direction defining portion is a planar antenna provided on the fifth surface.

According to the configuration of [5], by adjusting the arrangement, shape, or number of planar antennas, the beam profile of the output light can be freely designed.

[6] The laser module according to any one of [1] to [5], further comprising a reflective film provided on an end surface intersecting the first direction of a portion of the semiconductor multilayer structure including at least the active layer, and configured to reflect the first pump light and the second pump light.

According to the configuration of [6], the oscillation of the first pump light and the second pump light in the semiconductor multilayer structure (active layer) can be enhanced, and a terahertz wave can be generated with high efficiency.

[7] The laser module according to any one of [1] to [6], wherein the third surface of the substrate is a surface perpendicular to the first surface and the second surface.

Conventionally, in order to prevent total reflection of a terahertz wave at the terahertz-wave emission surface (the third surface), a polishing process may be performed to form that emission surface as an inclined surface. In contrast, with the configuration of [7], the terahertz wave is suitably propagated from the substrate to the resin layer by bringing the emission surface (the third surface) into contact with the resin layer, so such an inclined (polished) surface can be omitted. As a result, productivity of the laser module can be effectively improved.

[8] The laser module according to any one of [1] to [7], further comprising a reflection suppression structure provided in a portion including the third surface of the substrate or at a position facing the third surface, and configured to suppress reflection of the terahertz wave traveling from the substrate toward the resin layer back toward the substrate.

According to the configuration of [8], the propagation efficiency of the terahertz wave from the quantum cascade laser element (the substrate) to the resin layer can be improved.

[9] The laser module according to [8], wherein the reflection suppression structure is formed by a portion including the third surface of the substrate, and is formed such that, when viewed in the first direction, an area occupied by the substrate in a plane perpendicular to the second direction is gradually decreased as it goes along the second direction toward a side on which the emission direction defining portion is provided.

In the configuration of [9], the reflection suppression structure including the third surface of the substrate functions as an impedance matching layer. More specifically, the area occupied by the substrate along the emission direction of the terahertz wave is gradually reduced (in other words, the area occupied by the resin layer is gradually increased). Thus, the refractive index felt by the terahertz wave passing through a region where the substrate and the resin layer coexist is gradually changed from the index of the substrate to that of the resin layer. In this way, by avoiding an abrupt refractive-index change and instead gradually changing the refractive index felt by the terahertz wave, reflection of the terahertz wave trying to enter the resin layer back toward the quantum cascade laser element side can be effectively suppressed.

[10] The laser module according to [8], wherein the reflection suppression structure is provided at a position facing the third surface of the substrate, and is formed by a structure in which a plurality of high-refractive-index material layers made of a high-refractive-index material having a refractive index higher than that of the resin layer are provided at intervals along the second direction, and a portion of the resin layer enters between adjacent high-refractive-index material layers.

According to the configuration of [10], by providing a reflection suppression structure functioning as a broadband antireflection (AR) coating, terahertz waves attempting to enter the resin layer can be effectively prevented from being reflected back toward the quantum cascade laser element side.

[11] The laser module according to [10], wherein the plurality of high-refractive-index material layers are formed of the same material as the substrate.

According to the configuration of [11], by forming multiple grooves at intervals along the second direction in a tip portion of a substrate integrally formed as one piece, portions of the substrate left between these grooves can be used as the high-refractive-index material layers. As a result, such high-refractive-index material layers can be formed easily, improving the productivity of the laser module having the effect of [10].

[12] The laser module according to [10] or [11], wherein the plurality of high-refractive-index material layers are connected to the substrate.

According to the configuration of [12], the plurality of high-refractive-index material layers can be more stably supported.

Moreover, for example, by performing an operation such as groove formation on a single rectangular substrate member such that the grooves do not fully penetrate, the substrate and the plurality of high-refractive-index material layers can be connected easily, thereby improving the productivity of both the substrate and the reflection suppression structure (the plurality of high-refractive-index material layers).

[13] The laser module according to [8], wherein the reflection suppression structure is formed by an inclined surface provided on the third surface of the substrate, and the inclined surface is inclined with respect to the second direction, when viewed in the first direction, so as to suppress total reflection of the terahertz wave.

According to the configuration of [13], the inclined surface (the reflection suppression structure) provided on the third surface can suppress total reflection of the terahertz wave. As a result, when viewed in the first direction, a terahertz wave radiating outward in the second direction can be effectively prevented from being totally reflected at the third surface and returned toward the quantum cascade laser element side.

[14] The laser module according to [8], wherein the reflection suppression structure is formed by a subwavelength periodic structure provided at a position facing the third surface of the substrate, the subwavelength periodic structure is formed by a plurality of unit regions arranged two-dimensionally at a period shorter than the wavelength of the terahertz wave when viewed in the first direction, each of the plurality of unit regions is composed of a portion of the substrate and a portion of the resin layer, and a ratio of the resin layer in each of the plurality of unit regions gradually increases along the second direction toward a side on which the emission direction defining portion is provided.

According to the configuration of [14], providing a subwavelength periodic structure configured so that the ratio occupied by the resin layer gradually increases along the terahertz-wave emission direction can produce an effect similar to that of the impedance matching layer in [9]. Furthermore, by configuring a meta-lens with this subwavelength periodic structure, phase control of the terahertz wave can also be performed.

[15] The laser module according to any one of [1] to [14], wherein a thickness of the substrate in the first direction is at least half of a wavelength of the terahertz wave.

According to the configuration of [15], by setting the thickness of the substrate having the terahertz-wave emission surface (the third surface) to at least half of the wavelength of the terahertz wave, the extraction efficiency of the terahertz wave is improved. Moreover, as described above, because the resin layer is provided at least up to the height of the second surface of the substrate, the thicker the substrate becomes, the thicker the resin layer also becomes. This makes it easier to form the resin layer on the support body. Consequently, when laser modules are mass-produced, product-to-product manufacturing variations can be reduced, and yield can be increased.

[16] The laser module according to any one of [1] to [15], wherein the resin layer is provided so as to cover a side surface of the substrate that intersects a third direction perpendicular to both the first direction and the second direction.

According to the configuration of [16], the resin layer can improve support stability of the quantum cascade laser element in the third direction and suitably protect the quantum cascade laser element.

According to one aspect of the present disclosure, it is possible to provide a laser module that can improve productivity while enhancing the efficiency of extracting a terahertz wave to the outside.

### BRIEF DESCRIPTION 0F THE DRAWINGS

FIG. 1 is a plan view of a laser module of a first embodiment.

FIG. 2 is a cross-sectional view of the laser module taken along line II-II in FIG. 1.

FIG. 3 is a cross-sectional view of the laser module taken along line III-III in FIG. 1.

FIG. 4 is a cross-sectional view of the laser module taken along line IV-IV in FIG. 3.

FIG. 5 is a plan view of a laser module of a second embodiment.

FIG. 6 is a cross-sectional view of the laser module taken along line VI-VI in FIG. 5.

FIG. 7 is a plan view of a laser module of a third embodiment.

FIG. 8 is a cross-sectional view of the laser module taken along line VIII-VIII in FIG. 7.

FIG. 9 is a plan view of a laser module of a fourth embodiment.

FIG. 10 is a plan view of a laser module of a fifth embodiment.

FIG. 11 is a cross-sectional view of the laser module taken along line XI-XI in FIG. 10.

FIG. 12 is a plan view of a laser module of a sixth embodiment.

FIG. 13 is a cross-sectional view of the laser module taken along line XIII-XIII in FIG. 12.

### DETAILED DESCRIPTION

Embodiments of the present disclosure will be described in detail below with reference to the drawings. In the following description, the same or corresponding elements are denoted by the same reference numerals, and overlapping descriptions will be omitted. Also, words such as “upper” and “lower” are used for convenience based on the orientation shown in the drawings. In the drawings, some parts are exaggerated to clearly illustrate features of the embodiments.

Accordingly, dimensional ratios in the drawings may differ from actual dimensional ratios.

### First Embodiment

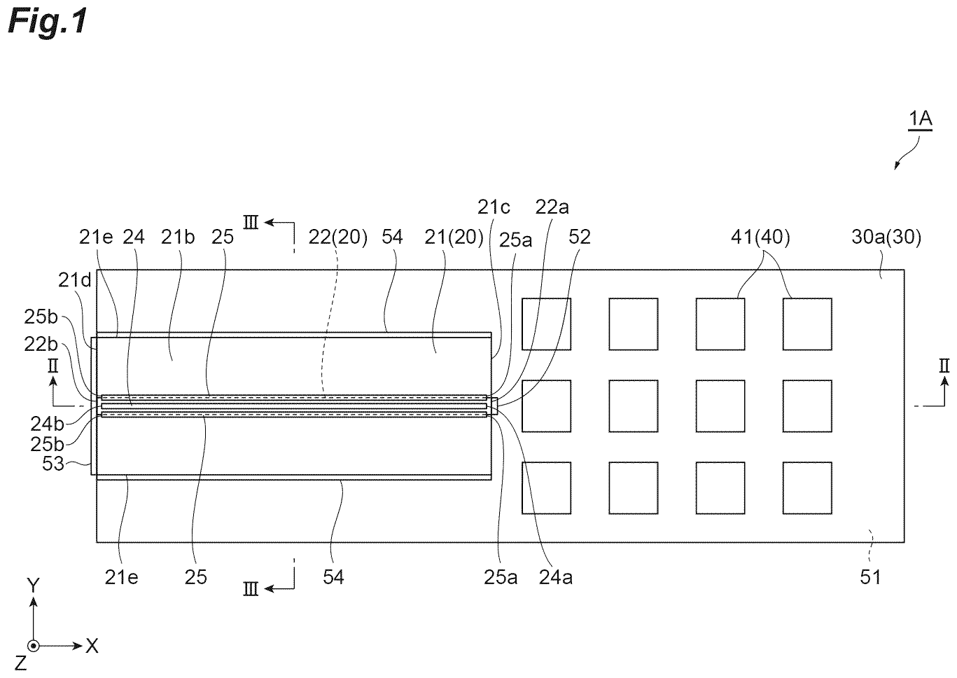

A laser module 1A according to a first embodiment will be described with reference to FIGS. 1 to 4. The laser module 1A includes a support substrate 10 (support body), a QCL element 20 (quantum cascade laser element), a resin layer 30, and an emission direction defining portion 40. The QCL element 20 is a difference-frequency-generation type terahertz quantum cascade laser (DFG-THz-QCL). By incorporating such a QCL element 20, the laser module 1A can emit a single-mode and wavelength-tunable terahertz wave, and it is configured to operate at room temperature.

### (Support Substrate)

The support substrate 10 is a member having a flat support surface 10a for placing the QCL element 20 and the resin layer 30. For example, the support substrate 10 is formed in a rectangular parallelepiped shape. The support substrate 10 may be, for example, an InP substrate. When the support substrate 10 is formed of a material that transmits the terahertz wave L (e.g., an InP substrate), a metal layer 51 (reflective layer) formed of a metal such as gold, platinum, silver, copper, aluminum, titanium, or nickel may be disposed on the support surface 10a. In other words, the QCL element 20 and the resin layer 30 may be disposed on the support surface 10a via the metal layer 51. The metal layer 51 prevents the terahertz wave L, which is emitted from the QCL element 20 toward the resin layer 30, from escaping into the support substrate 10. If the support substrate 10 is formed of a material that does not transmit the terahertz wave L (such as a metal), the metal layer 51 may be omitted.

### (QCL Element)

The QCL element 20 is disposed on the support surface 10a of the support substrate 10 via the metal layer 51. The QCL element 20 is a terahertz light source configured to output the terahertz wave L at room temperature. The QCL element 20 is formed in a rod shape. The QCL element 20 includes a substrate 21 and a semiconductor multilayer structure 22. In this embodiment, the QCL element 20 is formed as a ridge-stripe laser element using general semiconductor processes. The QCL element 20 can be obtained, for example, by forming InGaAs/InAlAs on the substrate 21 via epitaxial growth.

The substrate 21 is, for example, an InP single-crystal substrate (semi-insulating substrate: a high-resistivity semiconductor substrate with no doped impurities) in a rectangular parallelepiped shape. The substrate 21 has a lower surface 21a (first surface), an upper surface 21b (second surface), a front surface 21c (third surface), a rear surface 21d (end surface), and a pair of side surfaces 21e. In this specification, the direction in which the lower surface 21a and the upper surface 21b face each other is referred to as the vertical direction Z (the first direction).

The direction perpendicular to the vertical direction Z but along which the front surface 21c and the rear surface 21d face each other is referred to as the front-rear direction X (the second direction), and the direction perpendicular to both the vertical direction Z and the front-rear direction X, along which the pair of side surfaces 21e face each other, is referred to as the width direction Y (the third direction). In what follows, the side where the upper surface 21b is located relative to the lower surface 21a is referred to as “upward,” and the side where the front surface 21c is located relative to the rear surface 21d is referred to as “front.”

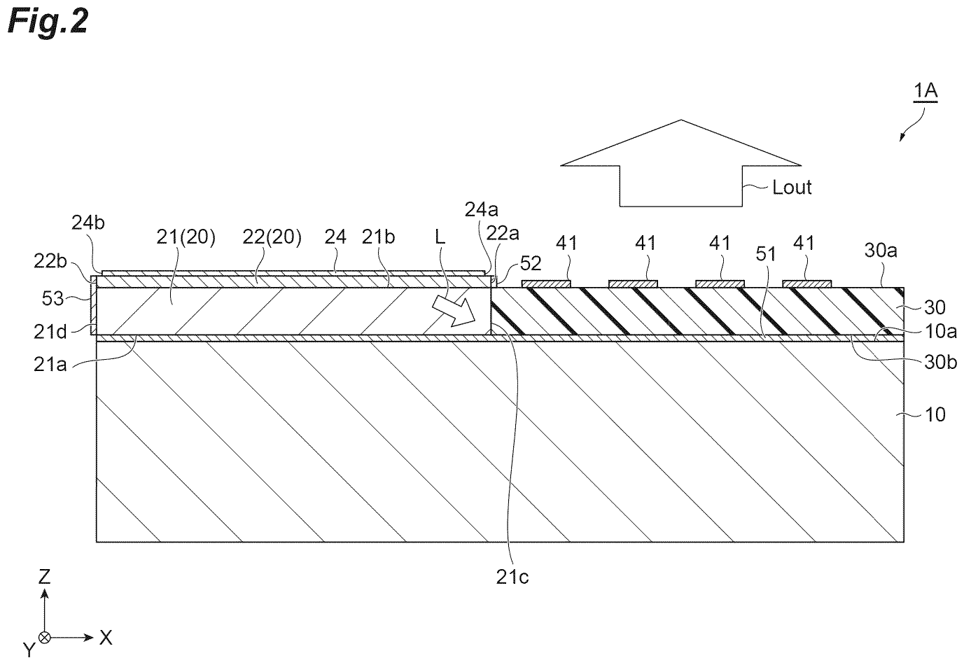

The lower surface 21a faces the support surface 10a (in this embodiment, it is supported by the support surface 10a via the metal layer 51). The upper surface 21b is disposed on a side opposite to the lower surface 21a in the vertical direction Z. The front surface 21c is a surface connecting the lower surface 21a and the upper surface 21b, and emits the terahertz wave L. As shown in FIG. 2, the front surface 21c is in contact with the resin layer 30. The terahertz wave L output forward from the front surface 21c propagates into the resin layer 30. The rear surface 21d is a surface opposite to the front surface 21c in the front-rear direction X. The pair of side surfaces 21e are surfaces intersecting the width direction Y.

The length of the substrate 21 in the front-rear direction X is approximately several hundred micrometers to several millimeters, the width in the width direction Y is approximately several hundred micrometers to several millimeters, and the thickness in the vertical direction Z is approximately several hundred micrometers. As one example, the substrate 21 may have a length of about 3 mm, a width of about 1 mm, and a thickness of about 500 μm. The terahertz wave L generated by difference frequency generation in an active layer 222 of the semiconductor multilayer structure 22 (described below) is propagated to the resin layer 30 through the substrate 21. From the standpoint of increasing extraction efficiency of the terahertz wave L through the substrate 21, it is preferable that the substrate 21 is, for example, a semi-insulating substrate as described above or a substrate with a carrier density of 1×10¹⁷ cm³ or lower.

The semiconductor multilayer structure 22 is provided on the upper surface 21b of the substrate 21. The thickness of the semiconductor multilayer structure 22 in the vertical direction Z is on the order of 10 μm to 20 μm. The semiconductor multilayer structure 22 has respective end surfaces 22a, 22b intersecting the front-rear direction X. The end surfaces 22a, 22b are surfaces perpendicular to the front-rear direction X. They may be, for example, cleavage planes formed by cleaving. The end surface 22a faces the front side (the side where the resin layer 30 is disposed). The end surface 22b is located on the opposite (rear) side from the end surface 22a. A resonator is defined between the end surfaces 22a and 22b. That is, mid-infrared light in a broad wavelength band (e.g., from 3 μm to 20 μm) generated within an active layer 222 namely, a first pump light of a first frequency ω₁ and a second pump light of a second frequency ω₂—are amplified by resonation between the end surfaces 22a and 22b.

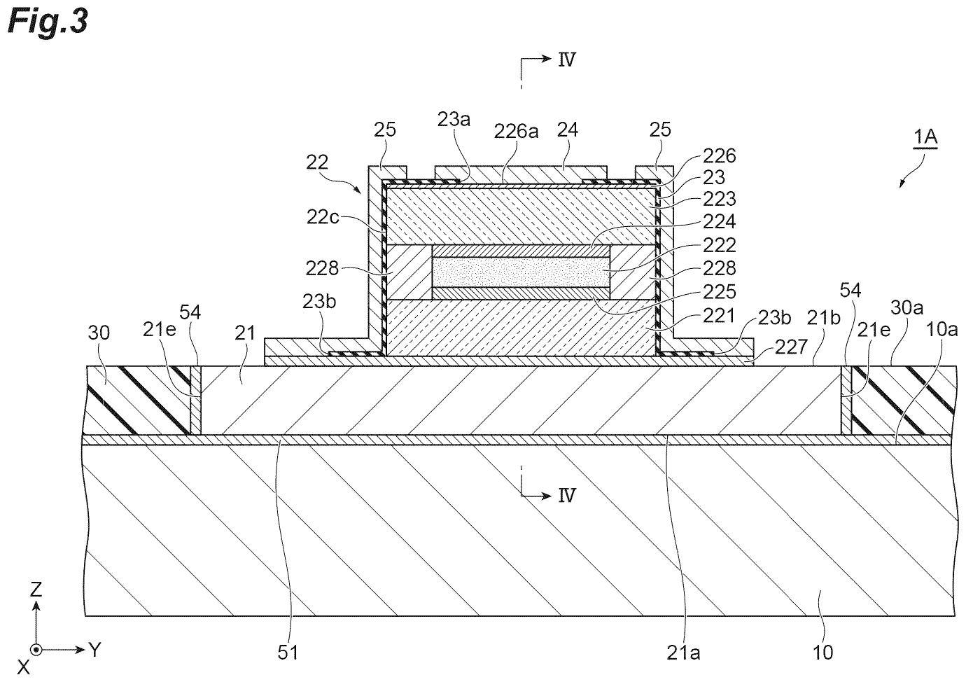

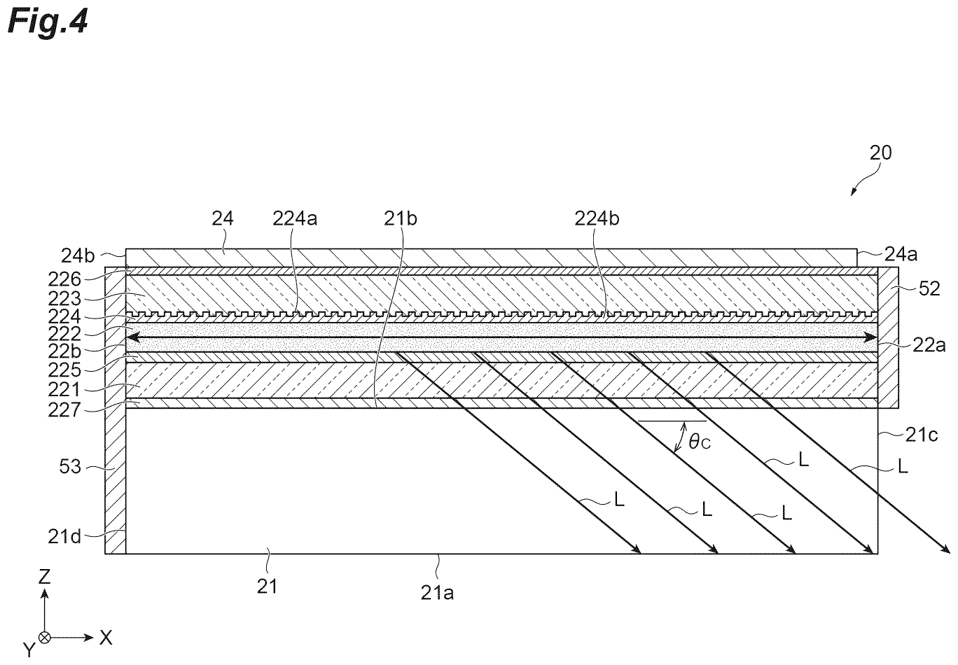

As shown in FIGS. 3 and 4, the semiconductor multilayer structure 22 has a lower cladding layer 221 (first cladding layer), the active layer 222, and an upper cladding layer 223 (second cladding layer). In this embodiment, in addition to those layers, the semiconductor multilayer structure 22 includes an upper guide layer 224, a lower guide layer 225, an upper contact layer 226, and a lower contact layer 227.

From the upper surface 21b side of the substrate 21, the lower contact layer 227, the lower cladding layer 221, the lower guide layer 225, the active layer 222, the upper guide layer 224, the upper cladding layer 223, and the upper contact layer 226 are stacked in this order. As shown in FIG. 3, support layers 228 are provided between the lower cladding layer 221 and the upper cladding layer 223 at both sides in the width direction Y of a ridge-stripe portion formed by the active layer 222, the upper guide layer 224, and the lower guide layer 225. Note that the lower contact layer 227 extends outward (in the width direction Y) beyond the lower cladding layer 221.

The lower contact layer 227 may be, for example, a highly doped Si-doped InGaAs layer (Si: 1.0×10¹⁸/cm³) with a thickness of about 400 nm, formed on the upper surface 21b of the substrate 21. The lower cladding layer 221 may be, for example, an Si-doped InP layer (Si: 1.5×10¹⁶/cm³) having a thickness of about 5 μm and formed on the lower contact layer 227. The lower guide layer 225 may be, for example, an Si-doped InGaAs layer (Si: 1.5×10¹⁶/cm³) with a thickness of about 250 nm and formed on the lower cladding layer 221.

The active layer 222, provided on the lower guide layer 225, is a layer in which a quantum cascade structure is formed. The active layer 222 has a cascade structure in which a quantum well emission layer (light-emitting layer) used for generating light and an electron-injection layer (injection layer) for injecting electrons (carriers) into the emission layer are alternately and repeatedly stacked in multiple stages.

Specifically, one period of the semiconductor multilayer structure including the emission layer and the injection layer is used as a single repeating unit, and this repeating unit is stacked in multiple stages to form the cascade structure in the active layer 222. Each of the emission layer and the injection layer, for example, may have a structure in which an InGaAs layer (well layer) and an InAlAs layer (barrier layer) are alternately stacked multiple times.

The upper guide layer 224 may be, for example, an Si-doped InGaAs layer (Si: 1.5×10¹⁶/cm³) with a thickness of about 450 nm and formed on the active layer 222. The upper cladding layer 223 may be, for example, an Si-doped InP layer (Si: 1.5×10¹⁶/cm³) with a thickness of about 5 μm, formed on the upper guide layer 224 and the support layers 228. The upper contact layer 226 may be, for example, a highly doped Si-doped InP layer (Si: 1.5×10¹⁸/cm³) of about 15 nm thickness, formed on the upper cladding layer 223. The support layers 228 may be, for example, Fe-doped InP layers.

As shown in FIG. 3, an insulating film 23 is provided so as to cover a top surface 226a of the upper contact layer 226, side surfaces 22c of the semiconductor multilayer structure 22 intersecting the width direction Y, and a portion of the lower contact layer 227. The insulating film 23 is formed, for example, of SiN. The insulating film 23 has an opening 23a formed to expose a part of the top surface 226a of the upper contact layer 226. The opening 23a extends in the front-rear direction X to expose a central portion in the width direction Y of the top surface 226a. Moreover, in the width direction Y, an end portion 23b of the insulating film 23 on the lower contact layer 227 is located inward of an end portion of the lower contact layer 227. In other words, the top surface of the lower contact layer 227 is exposed outward from the end portion 23b of the insulating film 23.

A first electrode 24 is formed on the top surface 226a of the upper contact layer 226. The first electrode 24 is formed of a metal such as Ti/Au, for example. The first electrode 24 is electrically connected to a part of the top surface 226a of the upper contact layer 226 through the opening 23a. As shown in FIGS. 1 and 2, the first electrode 24 extends in the front-rear direction X. A front end 24a of the first electrode 24 is located behind the end surface 22a of the semiconductor multilayer structure 22. A rear end 24b of the first electrode 24 is located ahead of the end surface 22b of the semiconductor multilayer structure 22. This arrangement prevents physical contact (conduction) between the first electrode 24 and metal films 52, 53 described below.

A second electrode 25 is formed on top of the lower contact layer 227 on the outside of the end portion 23b of the insulating film 23, where the lower contact layer 227 is exposed. The second electrode 25 is also formed of a metal such as Ti/Au. In this embodiment, the second electrode 25 is formed so as to cover a part of the side surface and top surface of the semiconductor multilayer structure 22, but it need not necessarily be formed in this manner. That is, as long as it is at least connected electrically to the lower contact layer 227 and spaced from the first electrode 24, the second electrode 25 may be formed in any suitable manner. As shown in FIG. 1, the second electrode 25, like the first electrode 24, extends in the front-rear direction X. A front end 25a and a rear end 25b of the second electrode 25 are located inside the end surfaces 22a, 22b of the semiconductor multilayer structure 22 in the front-rear direction X, just like the front end 24a and the rear end 24b of the first electrode 24. In other words, the front end 25a of the second electrode 25 is positioned behind the end surface 22a of the semiconductor multilayer structure 22, and the rear end 25b of the second electrode 25 is positioned ahead of the end surface 22b of the semiconductor multilayer structure 22. This arrangement prevents physical contact (conduction) between the second electrode 25 and the metal films 52, 53 described below. With this configuration, supplying current from the second electrode 25 to the first electrode 24 can drive the QCL element 20.

As one example, in the QCL element 20, two different diffraction grating layers 224a, 224b functioning as a distributed feedback (DFB) structure are provided in the upper guide layer 224. Thus, in the QCL element 20, generation of the first pump light (the first frequency ω₁) and the second pump light (the second frequency ω₂) and generation of the terahertz wave L of the difference frequency ω₃ (=|ω₁−ω₂|) of these lights can be realized. Note that the diffraction grating layers 224a, 224b may also be provided in a cladding layer (e.g., the upper cladding layer 223). Both the first pump light and the second pump light are mid-infrared light.

As noted above, in the semiconductor multilayer structure 22, the end surfaces 22a and 22b define a resonator that oscillates the first pump light and the second pump light. The active layer 222 generates the terahertz wave L having a difference frequency ω₃ (=ω₁−ω₂|) between the first frequency ω₁ of the first pump light and the second frequency ω₂ of the second pump light, through difference frequency generation with Cherenkov phase matching.

As shown in FIG. 4, the generated terahertz wave L is radiated in a direction (the emission direction) that is tilted downward (toward the substrate 21) by the Cherenkov radiation angle θ_{C} relative to the frontward direction along the resonator axis (the direction from the end surface 22b toward the end surface 22a). More specifically, the terahertz wave L generated in the active layer 222 propagates as a plane wave (i.e., in phase) in the substrate 21 at the radiation angle θ_{C} indicated by Equation (1) below. In Equation (1), n_{MIR} is the group refractive index of the substrate 21 for mid-infrared light, and n_{THz} is the refractive index of the substrate 21 for terahertz waves. The radiation angle θ_{C} depends on the material of the substrate 21 (i.e., the refractive index corresponding to that material) as well as the frequency of the terahertz wave L; for example, it may be from 5 to 30 degrees. In the present embodiment, as one example, θ_{C} is 20 degrees.

θ_{C}=cos⁻¹(n_{MIR}/n_{THz}) (1)

As shown in FIGS. 1, 2, and 4, a metal film 52 (reflective film) for reflecting the first pump light and the second pump light is provided on the end surface 22a of the semiconductor multilayer structure 22, and a metal film 53 (reflective film, reflective layer) for reflecting the first pump light and the second pump light is provided on the end surface 22b of the semiconductor multilayer structure 22. The metal films 52, 53 may be metal films made of, for example, the same material as the first electrode 24 and the second electrode 25 (such as Ti/Au). Although they may be omitted, providing the metal films 52, 53 can enhance laser oscillation of the first pump light and the second pump light between the end surfaces 22a and 22b, and thus improve the efficiency of generating the terahertz wave L by difference frequency generation.

As shown in FIG. 4, the metal film 52 is formed only on the end surface 22a of the semiconductor multilayer structure 22 so as not to impede propagation of the terahertz wave L from the front surface 21c into the resin layer 30, and it is not formed on the front surface 21c of the substrate 21. In contrast, the metal film 53 is formed continuously not only on the end surface 22b of the semiconductor multilayer structure 22 but also on the rear surface 21d of the substrate 21, in order to prevent the terahertz wave L from escaping rearward through the rear surface 21d.

As shown in FIGS. 2 and 3, a metal film 54 (reflective layer) for reflecting the terahertz wave L is formed on the pair of side surfaces 21e of the substrate 21. The metal film 54 may be, for example, a film made of the same material (e.g., Ti/Au) as the first electrode 24 and the second electrode 25.

### (Resin Layer)

The resin layer 30 is disposed on the support surface 10a of the support substrate 10 via the metal layer 51. In this embodiment, the resin layer 30 is provided so as to cover all portions on the support surface 10a (metal layer 51) where the QCL element 20 (the substrate 21) is not placed. That is, as shown in FIGS. 1 and 2, the resin layer 30 is placed in front of the QCL element 20, and as shown in FIGS. 1 and 3, it is also provided in side regions in the width direction Y—i.e., on both sides of the QCL element 20 facing the pair of side surfaces 21e. In other words, as shown in FIG. 3, a part of the resin layer 30 covers the side surfaces 21e of the substrate 21 via the metal film 54. It is not strictly necessary to provide the resin layer 30 in these side regions. However, by also providing the resin layer 30 in these side regions, it is possible to improve support stability of the QCL element 20 in the width direction Y and to suitably protect the QCL element 20.

The resin layer 30 has an upper surface 30a (the fifth surface) and a lower surface 30b (the fourth surface). The lower surface 30b faces the support surface 10a (in this embodiment, it is supported on the support surface 10a via the metal layer 51). The upper surface 30a is located on a side opposite to the lower surface 30b in the vertical direction Z. The resin layer 30 is at least in contact with the front surface 21c of the substrate 21. Further, as shown in FIGS. 1 and 2, the resin layer 30 extends in the front-rear direction X (i.e., when viewed in the vertical direction Z, along the emission direction of the terahertz wave L from the front surface 21c). More specifically, the resin layer 30 extends from the portion contacting the front surface 21c forward for at least some length sufficient to accommodate, for example, an area where a planar antenna 41 is placed (described below). As shown in FIG. 2, a height position of the upper surface 30a of the resin layer 30 relative to the support surface 10a reaches at least the height position of the upper surface 21b of the substrate 21 relative to the support surface 10a. In this embodiment, the upper surface 30a of the resin layer 30 is at approximately the same height as the upper surface 21b of the substrate 21. However, the resin layer 30 may be formed so that the upper surface 30a of the resin layer 30 extends above the upper surface 21b of the substrate 21.

### (Emission Direction Defining Portion)

The emission direction defining portion 40 is provided on the upper surface 30a of the resin layer 30. The emission direction defining portion 40 is configured to emit the terahertz wave L—as emitted from the front surface 21c of the substrate 21—out of the resin layer 30 from the upper surface 30a in a direction facing the upper surface 30a (i.e., upward). In other words, the emission direction defining portion 40 converts the terahertz wave L propagating in the interior of the resin layer 30 into output light Lout that is directed upward from the upper surface 30a.

The emission direction defining portion 40 may be formed by, for example, one or more planar antennas 41. In this embodiment, as one example, the emission direction defining portion 40 is configured as an antenna array including 12 planar antennas 41 arranged in a 3×4 matrix. By adjusting factors such as the arrangement (pitch), size, or shape of multiple planar antennas 41 with respect to the wavelength of the terahertz wave L that propagates through the interior of the resin layer 30, the radiation of the terahertz wave L can be given directivity (here, in the upward direction). Examples of the planar antenna 41 that may be used include patch antennas, bowtie antennas, dipole antennas, slot antennas, and radial line slot antennas. Note that, because the terahertz wave L emitted from the front surface 21c of the substrate 21 is also radiated in the width direction Y, as shown in FIG. 1, it is preferable for the width (Y-direction dimension) of the entire formation area of the emission direction defining portion 40 (i.e., the smallest rectangular region that includes all of the multiple planar antennas 41 when viewed in the vertical direction Z) to be larger than the width of the substrate 21. In this way, by making the emission direction defining portion 40 wider than the QCL element 20 (the substrate 21), it becomes possible to more efficiently extract radiation components of the terahertz wave L that spread in the width direction Y as the output light Lout.

### Effects of the First Embodiment

The laser module 1A is formed as a DFG-THz-QCL that generates the terahertz wave L by difference frequency generation. According to the laser module 1A, by bringing the resin layer 30—which has a smaller difference in refractive index from the substrate 21 of the QCL element 20 than does air-into contact with the front surface 21c of the substrate 21, total reflection of the terahertz wave L at the substrate's end surface (i.e., the interface between the front surface 21c and air) becomes suppressed. As a result, the terahertz wave L can be efficiently propagated from the substrate 21 of the QCL element 20 to the resin layer 30, and the terahertz wave L that passes through the interior of the resin layer 30 can be emitted in a direction (i.e., upward in this embodiment) determined by the emission direction defining portion 40 (the direction facing the upper surface 30a). Thus, according to the laser module 1A, productivity (yield) can be improved while also increasing the efficiency of extracting the terahertz wave L to the outside, through making the laser module 1A a relatively simple configuration.

As shown in FIG. 2, the metal layer 51, which reflects the terahertz wave L, is placed between the support surface 10a of the support substrate 10 and both the lower surface 21a of the substrate 21 and the lower surface 30b of the resin layer 30. With this configuration, in the QCL element 20, a terahertz wave L that is radiated obliquely downward (toward the support surface 10a) relative to the front-rear direction X (the arrows in FIGS. 2 and 4) from the front surface 21c of the substrate 21 is prevented from propagating into the support substrate 10 and instead is reflected by the metal layer 51 toward the resin layer 30 side. This allows a further improvement in the extraction efficiency of the terahertz wave L. That is, in the case where, as in this embodiment, a material that transmits the terahertz wave L (for example, an InP substrate similar to the substrate 21) is used as the support substrate 10, disposing the metal layer 51 prevents the terahertz wave L from escaping downward through the interior of the support substrate 10. Consequently, the final power of the output light Lout extracted upward can be enhanced. Note that, in this embodiment, the metal layer 51 covers the entire support surface 10a, including the side regions between the lower surface 30b of the resin layer 30 and the support surface 10a on both sides of the QCL element 20 in the width direction Y However, it is not strictly necessary to cover the entire support surface 10a with the metal layer 51. For example, the metal layer 51 may be omitted in the side regions.

As shown in FIG. 4, the metal film 53, functioning as a reflective layer for reflecting the terahertz wave L, is provided on the end surface (the rear surface 21d) of the substrate 21 located on the opposite side of the front surface 21c in the front-rear direction X. As mentioned above, in this embodiment, in the portion of the metal film 53 overlapping the end surface 22b of the semiconductor multilayer structure 22, it increases the reflectivity of the first pump light and the second pump light in the active layer 222 to enhance oscillation efficiency. Meanwhile, in the portion overlapping the rear surface 21d of the substrate 21, it prevents the terahertz wave L from escaping rearward. With this configuration, by reflecting the terahertz wave L frontward at the rear surface 21d of the substrate 21 by means of the metal film 53, the amount of terahertz-wave light traveling from the rear surface 21d toward the front surface 21c (i.e., ultimately propagating into the resin layer 30 and contributing to an increase in the output light Lout) can be increased. As a result, the extraction efficiency of the terahertz wave L can be even more effectively enhanced.

As shown in FIGS. 1 and 3, the metal film 54, functioning as a reflective layer for reflecting the terahertz wave L, is provided on the side surfaces 21e of the substrate 21 in the width direction Y With this configuration, the terahertz wave L trying to exit to the outside (in the outward width direction Y) from the side surfaces 21e of the substrate 21 can be reflected back into the substrate 21 by the metal film 54. Consequently, the amount of terahertz-wave light emitted from the front surface 21c can be increased, thereby further effectively improving the extraction efficiency of the terahertz wave L.

Each of the metal layer 51 and the metal films 53, 54 only needs to be capable of reflecting the terahertz wave L, and may be formed of a material other than a metal (e.g., a semiconductor material relatively highly doped with impurities, such as InP, InGaAs, GaAs, Si, etc.).

The emission direction defining portion 40 is a planar antenna 41 (an antenna array of multiple planar antennas 41 in this embodiment) provided on the upper surface 30a of the resin layer 30. With this configuration, by adjusting factors such as arrangement, shape, or number of the planar antennas 41, the beam profile of the output light Lout can be freely designed.

As shown in FIGS. 1, 2, and 4, the metal films 52 and 53, functioning as reflective films for reflecting the first pump light and the second pump light, are disposed on the respective end surfaces (the end surfaces 22a, 22b in this embodiment) intersecting the front-rear direction X in a portion of the semiconductor multilayer structure 22 that includes at least the active layer 222. This configuration promotes oscillation of the first pump light and the second pump light in the semiconductor multilayer structure 22 (the active layer 222), allowing generation of the terahertz wave L with high efficiency. The metal films 52 and 53 only need to be capable of reflecting the first pump light and the second pump light (mid-infrared light) and may be formed of a material other than a metal (e.g., a semiconductor material relatively highly doped with impurities, such as InP, InGaAs, GaAs, Si, etc.).

As shown in FIGS. 2 and 4, the front surface 21c of the substrate 21 is a surface perpendicular to both the lower surface 21a and the upper surface 21b. In other words, the front surface 21c is perpendicular to the front-rear direction X and parallel to both the width direction Y and the vertical direction Z. Conventionally, to prevent total reflection of the terahertz wave L on the emission surface (the front surface 21c), polishing is sometimes performed so that the emission surface (the front surface 21c) is inclined, when viewed in the width direction Y, with respect to the vertical direction Z. In contrast, in this embodiment, by bringing the emission surface (the front surface 21c) into contact with the resin layer 30, the terahertz wave L is suitably transmitted from the substrate 21 to the resin layer 30, and thus such an inclined (polished) surface can be omitted. As a result, the productivity of the laser module 1A can be effectively improved. Even in the laser module 1A, a conventional inclined surface may be formed on the front surface 21c. However, by bringing the front surface 21c into contact with the resin layer 30, the angle requirement for total reflection can be relaxed, making it possible to achieve sufficient effect even with a smaller inclination angle compared to conventional inclined surface. Therefore, even if an inclined surface is formed on the front surface 21c in the same manner as conventional practice, the polishing time and polishing amount can be reduced compared to the past, thus improving productivity of the laser module 1A.

It is preferable that the thickness of the substrate 21 in the vertical direction Z (500 μm in this embodiment) is at least a half of the wavelength of the terahertz wave L. With this configuration, because the thickness of the substrate 21 having the terahertz-wave emission surface (the front surface 21c) is set to at least a half of the wavelength of the terahertz wave L, the extraction efficiency of the terahertz wave L can be improved. Moreover, as mentioned above, because the resin layer 30 is provided at least up to the upper surface 21b of the substrate 21, as the substrate 21 becomes thicker, the resin layer 30 also becomes thicker. Thus, forming the resin layer 30 on the support substrate 10 becomes easier. Namely, by ensuring a certain minimum thickness for the resin layer 30, it can be formed more easily than if one tried to form an extremely thin resin layer. Consequently, when the laser module 1A is mass-manufactured, product-to-product manufacturing variation can be reduced, and yield can be enhanced.

### Second Embodiment

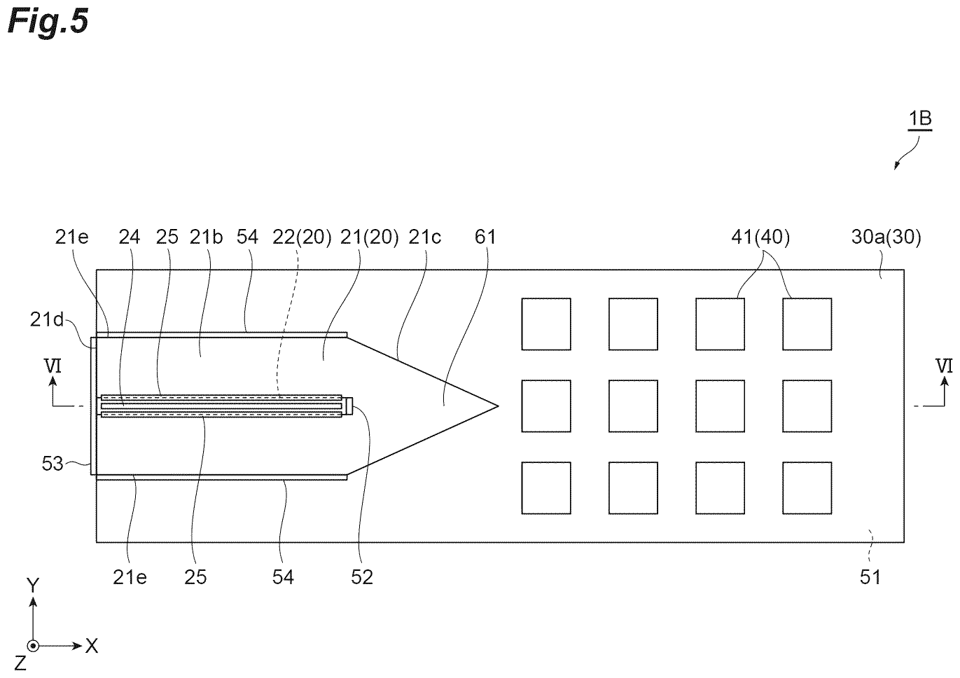

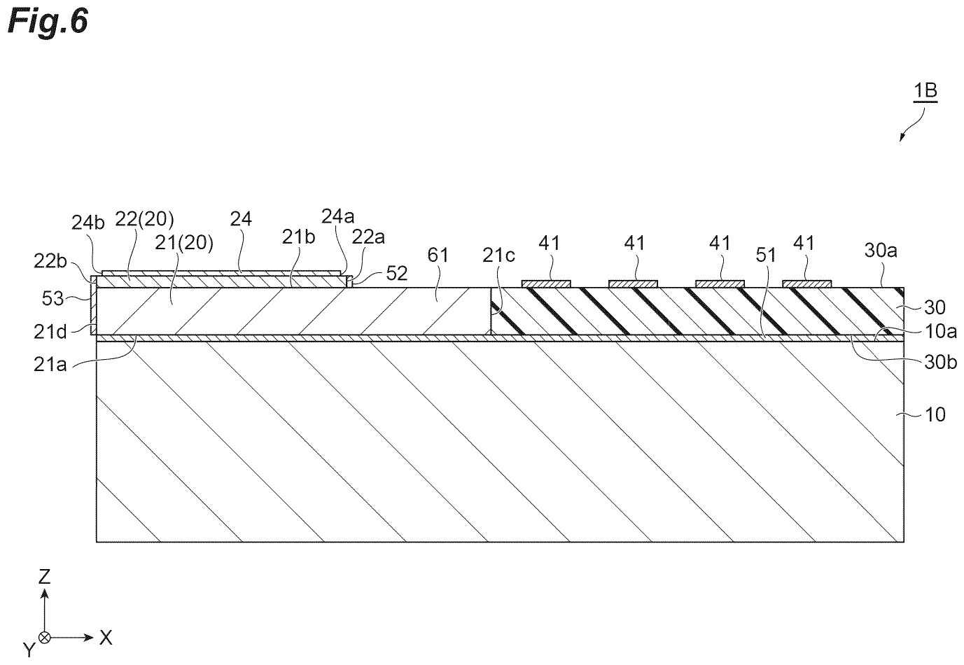

A laser module 1B according to a second embodiment will be described with reference to FIGS. 5 and 6. The laser module 1B differs from the laser module 1A in that it includes a reflection suppression structure 61 that suppresses reflection of the terahertz wave L-traveling from the substrate 21 toward the resin layer 30—back toward the substrate 21. Below, the configuration of the laser module 1B differing from the laser module 1A will primarily be explained, while details similar to those in the laser module 1A will be omitted.

The reflection suppression structure 61 is formed by a tip portion (front end portion) of the substrate 21 including the front surface 21c. As shown in FIG. 5, when viewed in the vertical direction Z, the reflection suppression structure 61 is formed as a triangular prism shape that narrows toward the front. In other words, in the plane perpendicular to the front-rear direction X (the YZ plane), the area occupied by the substrate 21 decreases gradually along the front-rear direction X toward the side where the emission direction defining portion 40 is placed. In the laser module 1A, the entire front surface 21c is perpendicular to the front-rear direction X. In contrast, in the laser module 1B, the tip portion (reflection suppression structure 61) shaped like a triangular prism is added.

In the laser module 1B, the reflection suppression structure 61 including the front surface 21c of the substrate 21 functions as an impedance matching layer. More specifically, it gradually reduces the area occupied by the substrate 21 (equivalently increases the area occupied by the resin layer 30) along the emission direction of the terahertz wave L (when viewed in the vertical direction Z, forward in the front-rear direction X). Thereby, the refractive index encountered by the terahertz wave L passing through a region where the substrate 21 and the resin layer 30 are mixed can be changed gradually from the refractive index of the substrate 21 to that of the resin layer 30. By avoiding an abrupt change in refractive index and instead providing a gradual change, it can effectively suppress the terahertz wave L from being reflected back toward the QCL element 20 when trying to enter the resin layer 30. As a result, propagation efficiency of the terahertz wave L from the QCL element 20 (the substrate 21) to the resin layer 30 can be enhanced, which in turn can effectively increase the output light Lout.

The shape of the reflection suppression structure 61 that functions as such an impedance matching layer to gradually change the refractive index is not limited to the triangular prism shape shown in FIG. 5. Although in the triangular prism example above, in the YZ plane, the cross-sectional area of substrate 21 is reduced linearly as it goes forward, one could adopt a shape in which the width progressively narrows in a non-linear (e.g., curved) manner toward the front when viewed in the vertical direction Z, or narrows stepwise in the width direction Y Nevertheless, forming the reflection suppression structure 61 as a triangular prism makes it easy to smoothly change the refractive index by linearly decreasing the area occupied by the substrate 21 in the YZ plane. Also, By cutting off both side portions of the tip portion of the substrate 21 in the width direction Y at an angle, the reflection suppression structure 61 can be easily manufactured.

### Third Embodiment

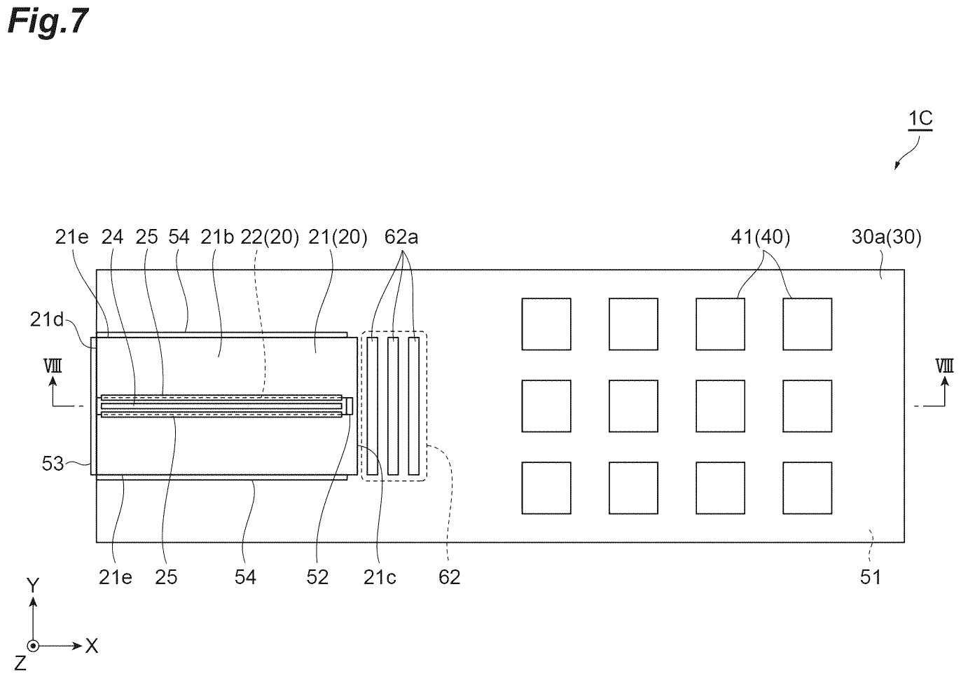

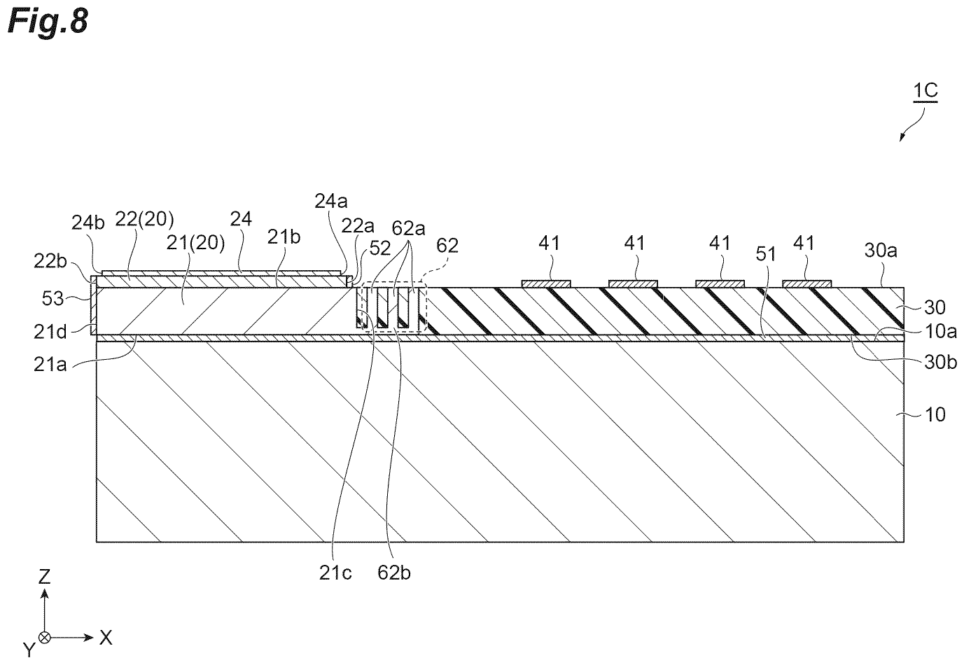

A laser module 1C according to a third embodiment will be described with reference to FIGS. 7 and 8. The laser module 1C differs from the laser module 1A in that it includes a reflection suppression structure 62 that suppresses reflection of the terahertz wave L-traveling from the substrate 21 toward the resin layer 30—back toward the substrate 21. Components of the laser module 1C that differ from those of the laser module 1A will be explained, and the same components will not be redundantly described.

In the laser module 1C, the front surface 21c is configured in the same way as in the laser module 1A, i.e., perpendicular to the front-rear direction X. The reflection suppression structure 62 is provided at a location facing the front surface 21c of the substrate 21. The reflection suppression structure 62 is formed of multiple high-refractive-index material layers 62a, made of a material having a refractive index higher than that of the resin layer 30, arranged with intervals along the front-rear direction X, such that portions of the resin layer 30 enter the spaces between adjacent high-refractive-index material layers 62a. In this embodiment, for example, three rectangular plate-shaped high-refractive-index material layers 62a are arranged facing the front surface 21c.

In the laser module 1C, a part of the resin layer 30 entering the spaces between the plurality of high-refractive-index material layers 62a functions as a low-refractive-index layer. Thus, by alternately arranging the high-refractive-index layers (the high-refractive-index material layers 62a) and the low-refractive-index layers (the portions of the resin layer 30), a reflection suppression structure 62 functioning as a broadband antireflection (AR) coating is realized. More specifically, by arranging multiple layers of high and low refractive indices and by adjusting each layer's thickness and the total number of layers, the reflection suppression structure 62 can function effectively as an AR coating. Design details such as the thickness of each layer and the number of layers are suitably determined to achieve satisfactory low-reflection performance for the terahertz wave L.

According to the laser module 1C, by providing the reflection suppression structure 62 functioning as an AR coating, terahertz waves L trying to enter the resin layer 30 can be effectively prevented from being reflected back toward the QCL element 20 side.

Furthermore, the plurality of high-refractive-index material layers 62a may be made of the same material as the substrate 21. With this configuration, by forming multiple grooves at intervals in the front-rear direction X in a tip portion of a rectangular parallelepiped substrate 21 that was originally integrally formed, portions of the substrate 21 left between those grooves can serve as the high-refractive-index material layers 62a. Because this makes the high-refractive-index material layers 62a easy to form, productivity of the laser module 1C can be improved.

Moreover, as shown in FIG. 8, in the laser module 1C, the plurality of high-refractive-index material layers 62a are connected to the substrate 21. For example, a groove portion (where a part of the resin layer 30 is entered) in the reflection suppression structure 62 is open to the upper surface 21b and the pair of side surfaces 21e of the substrate 21, but not to the lower surface 21a. In other words, the bottom of the grooves does not reach the lower surface 21a of the substrate 21. Thus, the high-refractive-index material layers 62a located between adjacent grooves are connected, via a plate-shaped portion 62b that includes the lower surface 21a of the substrate 21, at a location forward from the front surface 21c. With this configuration, the supporting stability of the plurality of high-refractive-index material layers 62a can be enhanced. Also, for example, by performing groove processing without penetrating down to the bottom of a single rectangular substrate, the substrate 21 and the plurality of high-refractive-index material layers 62a can be easily formed as an integral structure via the portion 62b, thereby improving productivity of both the substrate 21 and the reflection suppression structure 62 (the plurality of high-refractive-index material layers 62a).

Note that the plurality of high-refractive-index material layers 62a need not be connected to the substrate 21. For example, if the grooves described above are formed so as to extend from the upper surface 21b through to the lower surface 21a of the substrate 21, then the plurality of high-refractive-index material layers 62a will be mutually separate and also separated from the substrate 21. In that case, the plurality of high-refractive-index material layers 62a may be joined, for example, to the metal layer 51 (or, when the metal layer 51 is omitted, directly to the support surface 10a). Also, the high-refractive-index material layers 62a may be formed of a member different from that of the substrate 21. In such a case, they may be connected to the substrate 21 via the portion 62b or may be separated from the substrate 21.

### Fourth Embodiment

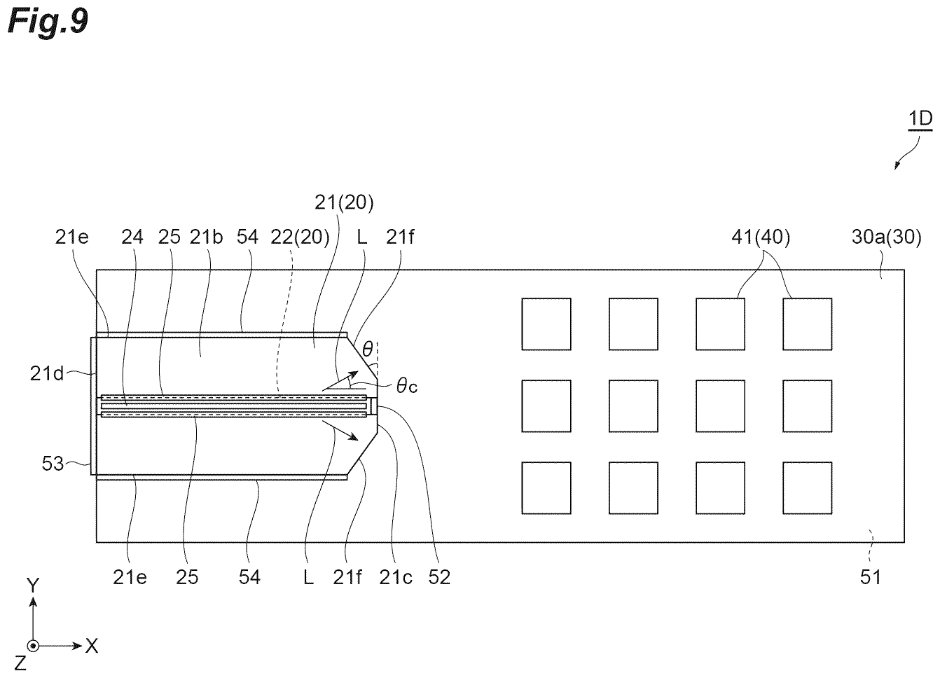

A laser module 1D according to a fourth embodiment will be described with reference to FIG. 9. The laser module 1D differs from the laser module 1A in that it includes inclined surfaces 21f functioning as a reflection suppression structure for suppressing reflection (i.e., total reflection) of the terahertz wave L back toward the substrate 21 side. Below, the configuration of the laser module 1D that differs from the laser module 1A will be focused on, and redundant descriptions are omitted.

As shown in FIG. 9, in the active layer 222 of the semiconductor multilayer structure 22, the terahertz wave L is radiated so as to spread in the width direction Y as well, at the radiation angle θ_{C} (Cherenkov radiation angle) described above when viewed in the vertical direction Z. If the terahertz wave L emitted in this manner can be prevented from totally reflecting at the front surface 21c and can be propagated into the resin layer 30, the output light Lout can be increased accordingly.

Hence, in the laser module 1D, both side portions of the front surface 21c in the width direction Y (the regions at which the terahertz wave L spreading in the width direction Y is incident) are cut diagonally along the vertical direction Z (i.e., inclined relative to the width direction Y). Thus, the inclined surfaces 21f are formed on a part of the front surface 21c. When viewed in the vertical direction Z, the inclined surface 21f is tilted with respect to the width direction Y so as to suppress total reflection of the terahertz wave L. In other words, when viewed in the vertical direction Z, the inclined surface 21f is set so that the incidence angle of the terahertz wave L to the inclined surface 21f is smaller than the incidence angle it would have if the front surface 21c (i.e., the YZ plane) were not inclined. More specifically, the inclined surface 21f is inclined rearward (away from the emission direction defining portion 40) as it extends outward from the center of the QCL element 20 in the width direction Y.

For example, the inclination angle θ of the inclined surface 21f with respect to the width direction Y is set to match or be close to the aforementioned radiation angle θ_{C} (Cherenkov radiation angle). This inclined surface 21f can be easily formed compared to the conventional polished surface (an inclined surface inclined with respect to the vertical direction Z when viewed in the width direction Y). Specifically, it can be easily formed by cutting straight down in the vertical direction Z at a position that does not overlap with the semiconductor multilayer body 22 in the vertical direction Z.

According to the laser module 1D, the inclined surface 21f (reflection suppression structure) provided on the front surface 21c can suppress the total reflection of the terahertz wave L. As a result, when viewed in the vertical direction Z, it is possible to effectively suppress the terahertz wave L radiated to the outside in the width direction Y from being totally reflected by the front surface 21c and returning to the QCL element 20 side. Consequently, the propagation efficiency of the terahertz wave L to the resin layer 30 can be increased, and ultimately, the output light Lout can be increased.

### Fifth Embodiment

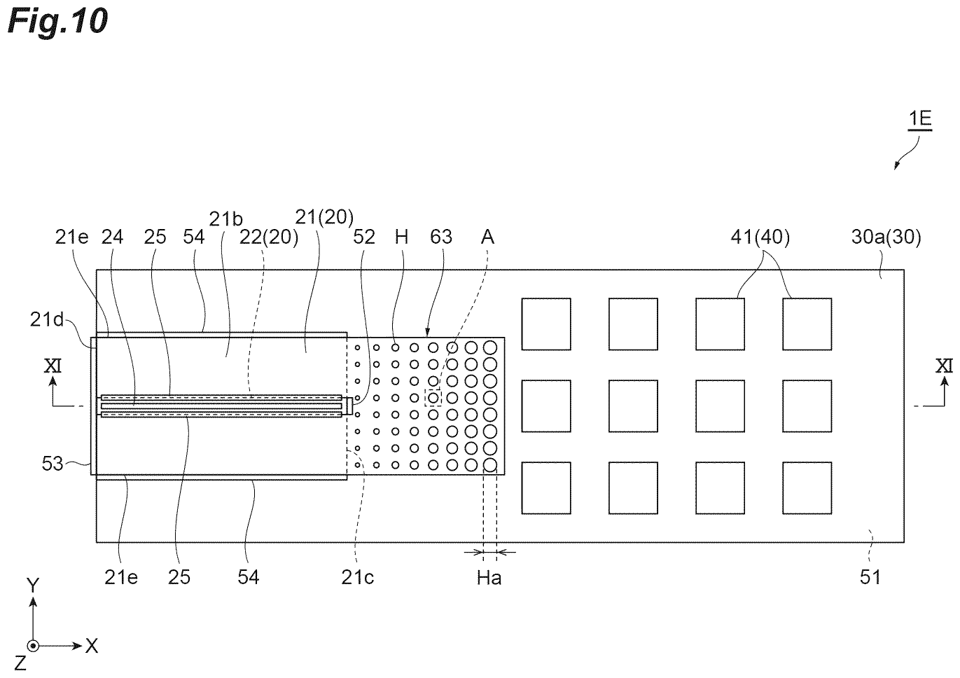

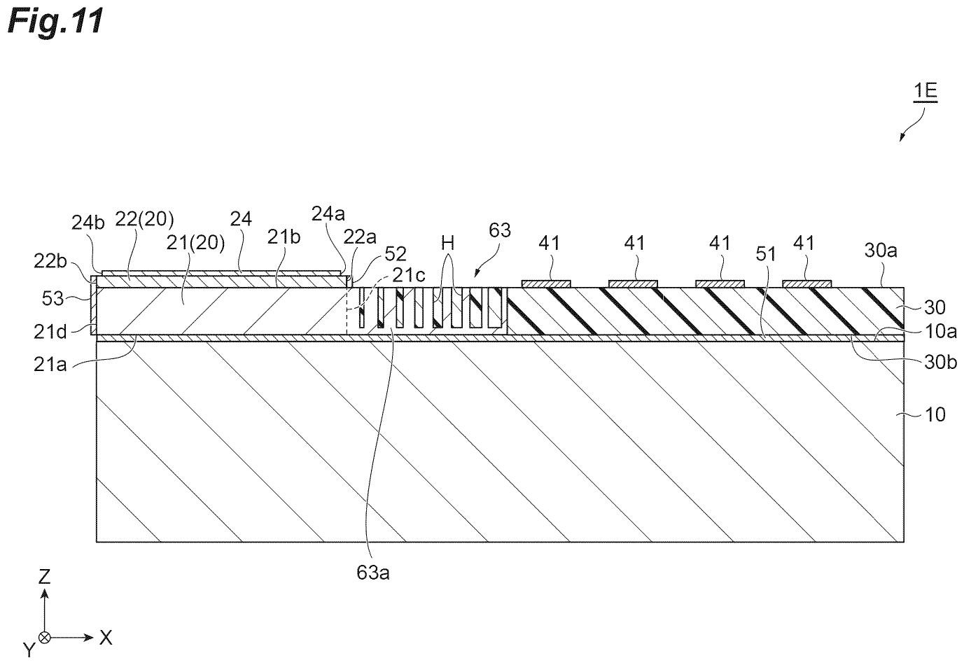

Referring to FIGS. 10 and 11, the laser module 1E of the fifth embodiment will be described. The laser module 1E differs from the laser module 1A in that it includes a reflection suppression structure 63 that suppresses the reflection of the terahertz wave L from the substrate 21 side towards the resin layer 30. Hereinafter, the configuration of the laser module 1E that differs from the laser module 1A will be mainly described, and the description of the configuration similar to the laser module 1A will be omitted.

The reflection suppression structure 63 is constituted by a sub-wavelength periodic structure provided at a position facing the front surface 21c of the substrate 21. The reflection suppression structure 63 (sub-wavelength periodic structure) is formed by a plurality of unit regions A arranged two-dimensionally with a period shorter than the wavelength of the terahertz wave L when viewed in the vertical direction Z. That is, the distance (period) between the centers of adjacent unit regions A is shorter than the wavelength of the terahertz wave L. As an example, the plurality of unit regions A are square-shaped regions when viewed in the vertical direction Z and are arranged in a square lattice pattern. Each of the plurality of unit regions A is constituted by a part of the substrate 21 and a part of the resin layer 30. That is, each unit region A is a region where the substrate 21 and the resin layer 30 are mixed. The proportion of the resin layer 30 in each of the plurality of unit regions A is configured to gradually increase toward the side where the emission direction defining portion 40 is provided along the front-rear direction X (i.e., forward).

In the laser module 1E, each unit region A is provided with a cylindrical hole H extending in the vertical direction Z at the center of the unit region A. The part of the unit region A where the hole H is not provided is constituted by the substrate 21. That is, one hole H formed by removing a part of the substrate 21 is provided at the center of one unit region A. Apart of the resin layer 30 is embedded inside the hole H.

As an example, the reflection suppression structure 63 is integrally formed with the substrate 21. That is, the tip portion of the substrate member integrally formed with the substrate 21 is the reflection suppression structure 63. In this case, the portion along the rear end surface of the first stage unit region A located at the rearmost position of the reflection suppression structure 63 (dashed line portion in FIG. 10) can be regarded as the front surface 21c of the substrate 21.

In the plurality of unit regions A, the depth of the hole H is constant. The bottom of the hole H does not reach the lower surface 21a of the substrate 21. As a result, the reflection suppression structure 63 has a plate-shaped bottom portion 63a continuously connected to the lower surface 21a of the substrate 21. On the other hand, in the plurality of unit regions A, the diameter Ha of the hole H is configured to gradually increase toward the front. This realizes a structure in which the proportion of the resin layer 30 in each of the plurality of unit regions A gradually increases toward the front. However, such a structure may also be realized by a configuration in which the depth of the hole H increases toward the front, or by a configuration in which both the diameter Ha and the depth of the hole H change.

According to the laser module 1E, by providing a sub-wavelength periodic structure (reflection suppression structure 63) configured such that the proportion of the resin layer 30 gradually increases along the emission direction of the terahertz wave L (the direction advancing forward when viewed in the vertical direction Z), the same effect as the impedance matching layer (reflection suppression structure 61) of the laser module 1B can be obtained. Furthermore, by constituting a meta-lens with the sub-wavelength periodic structure (reflection suppression structure 63), it is also possible to control the phase of the terahertz wave L (output light Lout).

### Sixth Embodiment

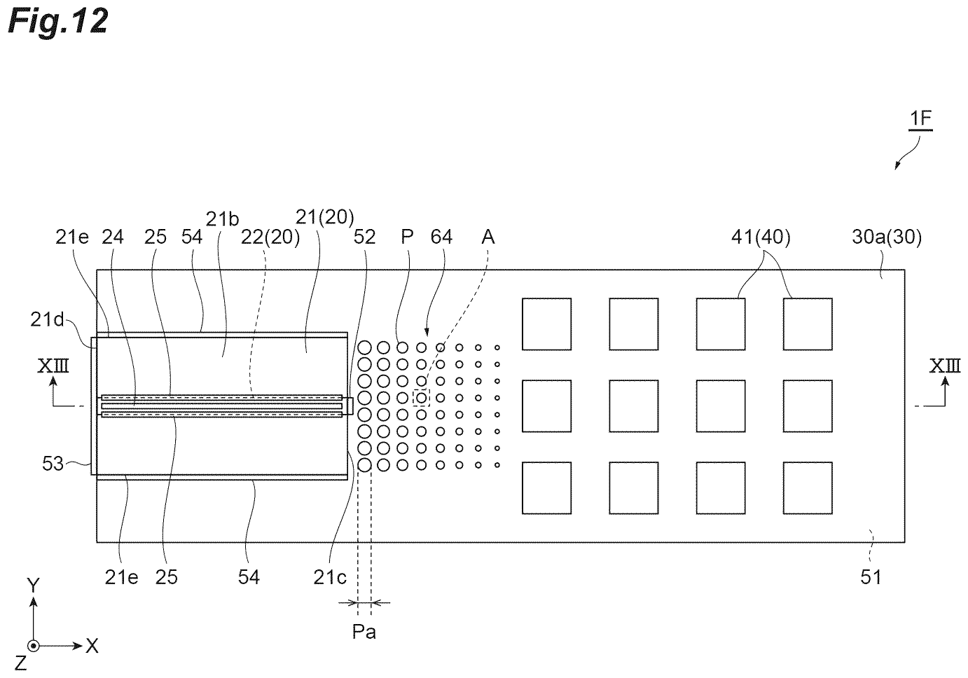

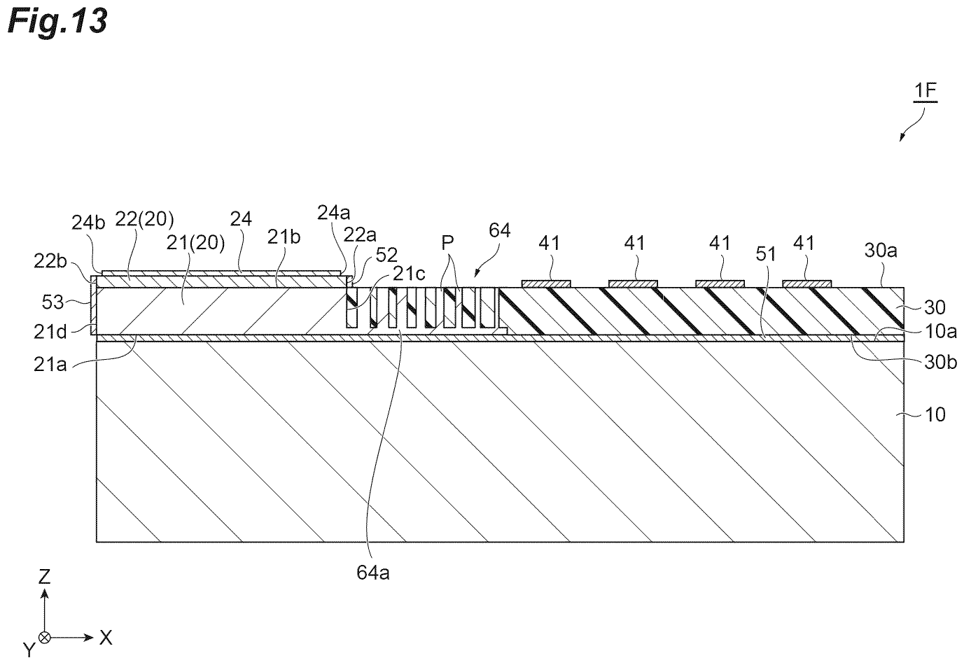

Referring to FIGS. 12 and 13, the laser module 1F of the sixth embodiment will be described. The laser module 1F differs from the laser module 1E in that it includes a reflection suppression structure 64 (pillar structure) in which a plurality of pillars P are periodically arranged, instead of the reflection suppression structure 63 (hole structure) in which a plurality of holes H, each partially embedded with the resin layer 30, are periodically arranged.

In the laser module 1F, each unit region A is provided with a cylindrical pillar P extending in the vertical direction Z at the center of the unit region A. In the unit region A, the pillar P is constituted by the substrate 21. On the other hand, in the part of the unit region A where the pillar P is not provided, the resin layer 30 is filled.

In the plurality of unit regions A, the height of the pillar P is constant. The reflection suppression structure 64 has a plate-shaped bottom portion 64a continuously connected to the lower surface 21a of the substrate 21. The plurality of pillars P are erected on the bottom portion 64a. On the other hand, in the plurality of unit regions A, the diameter Pa of the pillar P is configured to gradually decrease toward the front. This realizes a structure in which the proportion of the resin layer 30 in each of the plurality of unit regions A gradually increases toward the front. However, such a structure may also be realized by a configuration in which the height of the pillar P decreases toward the front, or by a configuration in which both the diameter Pa and the height of the pillar P change.

The laser module 1F provided with such a reflection suppression structure 64 (pillar structure) can also obtain the same effect as the laser module 1E provided with the above-described reflection suppression structure 63 (hole structure).

### [Modification]

As described above, several embodiments (first embodiment to sixth embodiment) of the laser module have been described, but the present disclosure is not limited to these embodiments. The materials and shapes of each configuration are not limited to the specific materials and shapes described above, and various materials and shapes other than those described above can be adopted. In addition, some configurations included in one embodiment may be omitted or changed as appropriate, and may be arbitrarily combined with configurations included in other embodiments.

For example, in the above embodiments, the QCL element 20 is configured to oscillate the first pump light and the second pump light alone, but a Littrow-type resonator may be configured between the QCL element 20 and an external resonator (e.g., a movable diffraction grating disposed at a position facing the end surface 22b). In this case, the metal film 53 covering the end surface 22b is omitted.

In the above embodiments, an antenna array composed of a plurality of planar antennas 41 is used as the emission direction defining portion 40, but the emission direction defining portion 40 may be constituted by a single antenna or may be realized by a structure other than an antenna. For example, the emission direction defining portion 40 may be realized by a grating structure provided on the upper surface 30a of the resin layer 30.

In the above embodiments, the width (length in the width direction Y) of the support substrate 10 is made larger than the width of the QCL element 20 (substrate 21), and the resin layer 30 is also provided on both sides in the width direction Y of the QCL element 20 (i.e., the side regions facing the pair of side surfaces 21e), but the width of the support substrate 10 may be approximately the same as the width of the QCL element 20. In this case, since the support surface 10a extending to the side regions is not formed, the resin layer 30 in the side regions may be omitted. By thus reducing the width of the support substrate 10 to the minimum necessary width for supporting the QCL element 20 (substrate 21), the overall width size of the laser module can be made compact.

What is claimed is:

1. A laser module comprising:
a support body having a support surface;
a quantum cascade laser element disposed on the support surface;
a resin layer disposed on the support surface; and
an emission direction defining portion disposed on the resin layer,
wherein the quantum cascade laser element includes:
a substrate having a first surface facing the support surface, a second surface on an opposite side of the first surface, and a third surface connecting the first surface and the second surface and configured to emit a terahertz wave; and
a semiconductor multilayer structure provided on the second surface of the substrate, the semiconductor multilayer structure including an active layer configured to generate a first pump light of a first frequency and a second pump light of a second frequency, and generate the terahertz wave of a difference frequency between the first frequency and the second frequency by difference frequency generation using the first pump light and the second pump light,
wherein the resin layer has a fourth surface facing the support surface and a fifth surface on an opposite side of the fourth surface,
wherein the emission direction defining portion is provided on the fifth surface and is configured to emit the terahertz wave emitted from the third surface of the substrate to an outside from the fifth surface in a direction facing the fifth surface,
wherein the resin layer is in contact with the third surface of the substrate and extends in a second direction along an emission direction of the terahertz wave from the third surface when viewed in a first direction in which the first surface and the second surface face each other, and
wherein a height position of the fifth surface of the resin layer with respect to the support surface reaches at least a height position of the second surface of the substrate with respect to the support surface.

2. The laser module according to claim 1, further comprising a reflective layer disposed between the support surface of the support body and the first surface of the substrate, and between the support surface of the support body and the fourth surface of the resin layer, and configured to reflect the terahertz wave.

3. The laser module according to claim 1, further comprising a reflective layer provided on an end surface of the substrate in the second direction on a side opposite to the third surface, and configured to reflect the terahertz wave.

4. The laser module according to claim 1, further comprising a reflective layer provided on a side surface of the substrate intersecting a third direction that is perpendicular to both the first direction and the second direction, and configured to reflect the terahertz wave.

5. The laser module according to claim 1,
wherein the emission direction defining portion is a planar antenna provided on the fifth surface.

6. The laser module according to claim 1, further comprising a reflective film provided on an end surface intersecting the first direction of a portion of the semiconductor multilayer structure including at least the active layer, and configured to reflect the first pump light and the second pump light.

7. The laser module according to claim 1,
wherein the third surface of the substrate is a surface perpendicular to the first surface and the second surface.

8. The laser module according to claim 1, further comprising a reflection suppression structure provided in a portion including the third surface of the substrate or at a position facing the third surface, and configured to suppress reflection of the terahertz wave traveling from the substrate toward the resin layer back toward the substrate.

9. The laser module according to claim 8,
wherein the reflection suppression structure is formed by a portion including the third surface of the substrate, and is formed such that, when viewed in the first direction, an area occupied by the substrate in a plane perpendicular to the second direction is gradually decreased as it goes along the second direction toward a side on which the emission direction defining portion is provided.

10. The laser module according to claim 8,
wherein the reflection suppression structure is provided at a position facing the third surface of the substrate, and is formed by a structure in which a plurality of high-refractive-index material layers made of a high-refractive-index material having a refractive index higher than that of the resin layer are provided at intervals along the second direction, and a portion of the resin layer enters between adjacent high-refractive-index material layers.

11. The laser module according to claim 10,
wherein the plurality of high-refractive-index material layers are formed of the same material as the substrate.

12. The laser module according to claim 11,
wherein the plurality of high-refractive-index material layers are connected to the substrate.

13. The laser module according to claim 8,
wherein the reflection suppression structure is formed by an inclined surface provided on the third surface of the substrate, and
the inclined surface is inclined with respect to the second direction, when viewed in the first direction, so as to suppress total reflection of the terahertz wave.

14. The laser module according to claim 8,
wherein the reflection suppression structure is formed by a subwavelength periodic structure provided at a position facing the third surface of the substrate,
the subwavelength periodic structure is formed by a plurality of unit regions arranged two-dimensionally at a period shorter than the wavelength of the terahertz wave when viewed in the first direction,
each of the plurality of unit regions is composed of a portion of the substrate and a portion of the resin layer, and
a ratio of the resin layer in each of the plurality of unit regions gradually increases along the second direction toward a side on which the emission direction defining portion is provided.

15. The laser module according to claim 1,
wherein a thickness of the substrate in the first direction is at least half of a wavelength of the terahertz wave.

16. The laser module according to claim 1,
wherein the resin layer is provided so as to cover a side surface of the substrate that intersects a third direction perpendicular to both the first direction and the second direction.
